(19) United States
(12) Patent Application Publication
(10) Pub. No.: US 2003/0213892 A1
(43) Pub. Date: Nov. 20, 2003

(54) Method and apparatus for determining optical flow

(75) Inventors: Wenyi Zhao, Somerset, NJ (US); Harpreet Singh Sawhney, West Windsor, NJ (US)

Correspondence Address: MOSER, PATTERSON & SHERIDAN, LLP, /SARNOFF CORPORATION, 595 SHREWSBURY AVENUE, SUITE 100, SHREWSBURY, NJ, 07702, US

(73) Assignee: Sarnoff Corporation

(21) Appl. No.: 10/440,966

(22) Filed: May 19, 2003

Related U.S. Application Data
(60) Provisional application No. 60/381,506, filed on May 17, 2002.

(51) Int. Cl. H01L 27/00

(52) U.S. Cl. 250/208.1

(57) ABSTRACT

A method and apparatus for determining the optical flow of a sequence of image frames. Optical flow fields are computed in a manner that enforces both brightness constancy and a consistency constraint.

### CROSS-REFERENCE TO RELATED APPLICATIONS

This application claims the benefit of U.S. provisional patent application serial No. 60/381,506 filed May 17, 2002, which is herein incorporated by reference.

### BACKGROUND OF THE INVENTION

1. Field of the Invention

Embodiments of the present invention relate to optical flow image processing. More particularly, this invention relates to determining optical flow with enforced consistency between image frames.

2. Description of the Related Art

Optical flow has been an essential parameter in image processing. For example, optical flow can be used in image processing methods for detecting salient motion in an image sequence or for super-resolution image reconstruction. There are different methods in the computation of optical flow that are deployed to address different implementations. For example, an optical flow field can be a two-dimensional (2D) vector representation of motion at pixel locations between two images.

There are many issues surrounding optical flow computation. For example, reconstruction-based super-resolution from motion video has been an active area of study in computer vision and video analysis. Image alignment is a key component of super-resolution methods. Unfortunately, standard methods of image alignment may not provide sufficient alignment accuracy for creating super-resolution images.

Therefore, a method and apparatus for determining optical flow would be useful. In particular, a method for determining consistent optical flow fields over multiple frames would be particularly useful.

### SUMMARY OF THE INVENTION

The present invention provides for optical flow field computational methods that have bidirectional consistency for a pair of image frames, which can lead to improved accuracy. Such optical flow field methods can extend the consistency principle to multiple image frames. Flow consistency implies that the flow computed from frame A to frame B is consistent with that computed from frame B to frame A.

The present invention also provides devices that compute optical flow fields in a consistent manner. Additionally, the present invention also extends the present novel approach to optical flow field computational methods for multiple frames.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a block diagram of an image processing system of the present invention;

FIG. 2 illustrates a block diagram of an image processing system of the present invention implemented via a general purpose computer;

FIG. 3 illustrates a flow diagram of the present invention;

FIG. 4 illustrates a pair of flow vectors from frame I₂ to frame I₁, and vice-versa through one-sided flow methods that do not enforce consistency;

FIG. 5 illustrates the effect of a consistency constraint placed on the optical flow between two frames;

FIG. 6 illustrates the relationship of a reference frame with frames I₁ and I₂; and

FIG. 7 illustrates the relationship of a reference frame with a sequence of frames I₁, I₂, . . . , Iₙ₋₁ and Iₙ.

### DETAILED DESCRIPTION

The present invention provides methods and apparatus for computing optical flow that enforce consistency, which can lead to improved accuracy. Optical flow consistency implies that the computed optical flow from frame A to frame B is consistent with that computed from frame B to frame A.

One approach in the computation of optical flow is based on a premise of brightness constancy between pairs of image frames I₁ and I₂,

I₁(p₁)=I₂(p₂), (equ, 1)

where p₁ and p₂ are the coordinates of image frames I₁ and I₂ respectively.

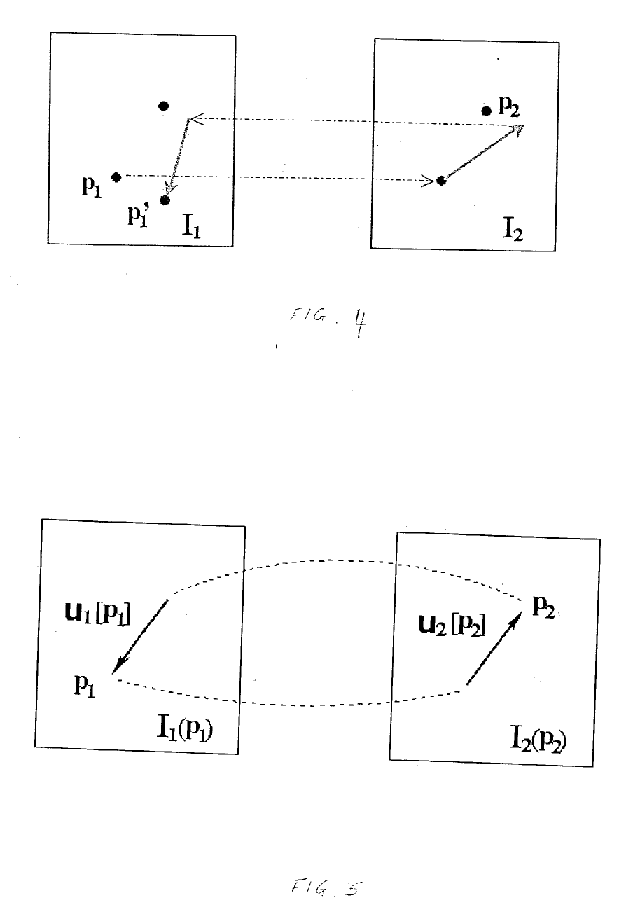

Flow accuracy, a measure of the absolute flow error, is a basic issue with any optical flow computational method. The actual optical flow should be consistent, i.e., there is only one true optical flow field between any pair of image frames. However, for most optical flow computational methods, there is no guarantee of consistency. This inconsistency (FIG. 4) is illustrated when the optical flow field is computed from frame A to frame B (e.g., forward flow), and then the optical flow field is computed from frame B to frame A (e.g., backward flow). Ideally, the calculated optical flow fields should be consistent in that the two calculated flow fields represent the same flow field, but it is often the case that there is inconsistency between the forward flow and the backward flow. The reprojection error flow is defined as the difference between the forward flow and the backward flow at corresponding points. Additionally, it is clear that two flow computations are necessary to generate the forward flow and the backward flow.

In general, computational practice has been to either compute a correlation score between image frames, or to discard image sections that exceed a threshold. In some applications, one-sided optical flow methods are independently applied in the two directions, and points where the two flows are inconsistent are simply rejected. Unfortunately, this produces sparser flow fields and inaccurate flow estimates.

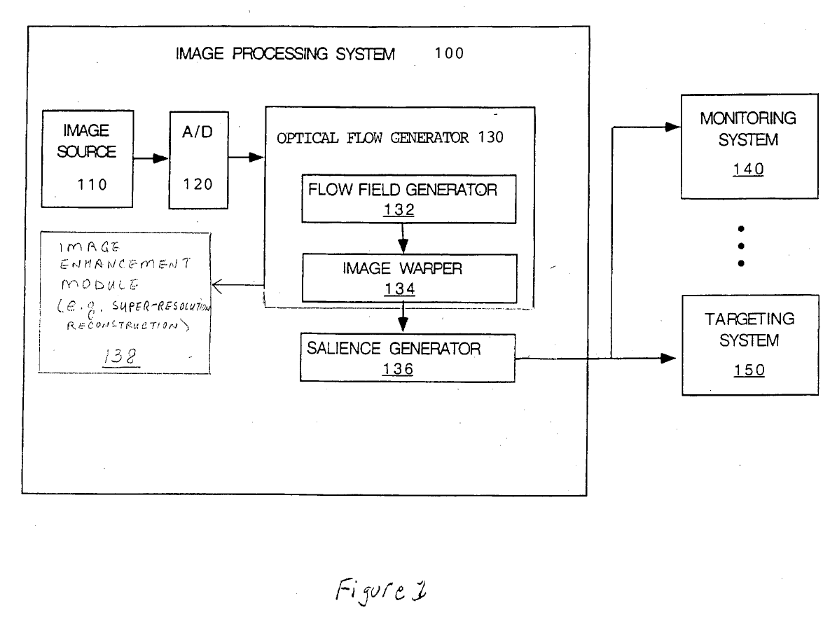

The problem of sparse and inaccurate flow estimation based on pairs of sequential image frames is a significant obstacle to general super-resolution methods that depends on highly accurate flow fields with 100% density. While in the present invention, multiple frames are used simultaneously to estimate dense and accurate flows. FIG. 1 illustrates a block diagram of an image processing system 100 for practicing the present invention. The image processing system 100 includes an image source 110, an analog to digital (A/D) converter 120, an optical flow generator 130, a salience generator 136, and an image enhancement module 138. In one embodiment, the optical flow generator 130 and the salience generator 136 can be deployed as a motion detector. Alternatively, the optical flow generator 130 and the image enhancement module 138 can be deployed as an image enhancer for generating reconstruction-based super-resolution images. Thus, depending on the requirement of a particular implementation, various components in FIG. 1 can be omitted or various other image processing components can be added.

The image source 110 may be any of a number of analog imaging devices such as a camera, a video cassette recorder (VCR), or a video disk player. The analog image signal from the image source is digitized by the A/D converter 120 into image frame based digitized signals. While FIG. 1 illustrates an analog source that is subsequently digitized, in other applications the image source itself could produce digitized information. For example, an image source could be a digital storage medium with stored digital image information or a digital camera. In that case, the digitized image information is directly applied to the optical flow generator 130, thereby bypassing the A/D converter 120. Either way, the optical flow generator 130 received digitized image signals that are applied in image frames, with each frame being comprised of a plurality of pixels.

In one embodiment, the optical flow generator 130 and salience generator 136 are deployed to detect salient motion between the image frames. The optical flow generator 130 comprises an optical flow field generator 132, and an image warper 134 and a salience generator 136. The salience measurement produced by the salience generator 136 can be used by other systems, such as a monitoring system 140 that detects moving objects or a targeting system 150 that targets a weapon.

The salience generator 136 detects salient motion by determining image frame-to-image frame optical flow data such that for each pixel it is possible to estimate the image distance it has moved over time. Thus, the salience of a person moving in one direction will increase; whereas, the salience of a moving tree branch will fluctuate between two opposite-signed distances. A computational method of determining optical flows in accord with the present invention is described below. A disclosure of using optical flow in such implementations can be found in U.S. Pat. No. 6,303,920, which is commonly assigned to the present assignor and is herein incorporated by reference.

In an alternate embodiment, the optical flow generator 130 and image enhancement module 138 are deployed to generate reconstruction-based super-resolution images. Namely, the optical flow generator 130 generates optical flows that can then be used by the enhancement module 138, e.g., in the context of accurate image alignment, to generate reconstruction-based super-resolution images when super-resolution methods are executed.

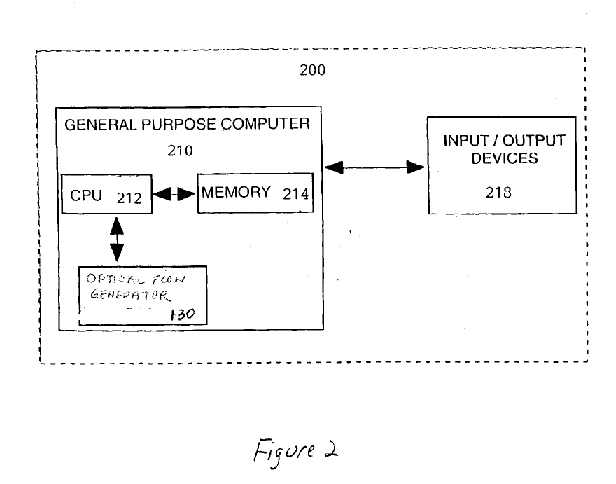

FIG. 2 illustrates a block diagram of an image processing system 200 that implements the present invention using a general purpose computer 210. The general purpose computer 210 includes a central processing system 212, a memory 214, and one or more image processing modules, e.g., an optical flow generator 130, a salience generator 136 and an image enhancement module 138 as disclosed above.

Furthermore, the image processing system 200 includes various input/output devices 218. A typical input/output device 218 might be a keyboard, a mouse, an audio recorder, a camera, a camcorder, a video monitor, any number of imaging devices or storage devices, including but not limited to, a tape drive, a floppy drive, a hard disk drive or a compact disk drive.

When viewing FIGS. 1 and 2 it should be understood that the image source 110 and the analog to digital (A/D) converter 120 of FIG. 1 are implemented either in the input/out devices 218, the central processing system 212, or in both. It should also be understood that the optical flow generator 130 can be implemented as a physical device, a software application, or a combination of software and hardware. Furthermore, various data structures generated by the optical flow generator 130, such as optical flow fields, warped images, cumulative flow, and salience measures, can be stored on a computer readable medium, e.g., RAM memory, magnetic or optical drive or diskette and the like.

Specifically, the optical flow field generator 132 computes image frame-to-image frame optical flow fields, from two or more successive image frames. As noted above, an optical flow filed can be computed between an image pair I₁(p₁)=I₂(p₂) based on brightness constancy (where p₁ and p₂ are the coordinates of frames 1 and 2). At each iteration, a linearized approximation to the above equation is employed to solve for increments in the flow field:

Iₜ(p₂)≈∇I₂(p₂)^{T}J₁₂^{T}u₂[p₂], (Equ. 2)

where J₁₂ is the Jacobian partial derivative matrix of p₁ with respect to p₂. That equation is the basis of the one-sided iterative, multi-grid algorithms that compute the optical flow fields from I₁ to I₂. An approximation of the Jacobian J₁₂ is:

$${J}_{12} ∇ {I}_{2} ( {p}_{2} ) ≃ \frac{1}{2} ( ∇ {I}_{2} ( {p}_{2} ) + ∇ {I}_{1} ( {p}_{2} ) ) \qquad ( Equ . 3 )$$

The above formulas can be used to compute a pair of flow fields from I₁ to I₂, and vice-versa. However, the computed flows in different directions are, in general, different. This difference is shown in FIG. 4. That is, computational methods often do not enforce the following consistency constraint:

p₂=p₁+u₁[p₁] u₂[p₂]=−u₁[p₁] (Equ. 4)

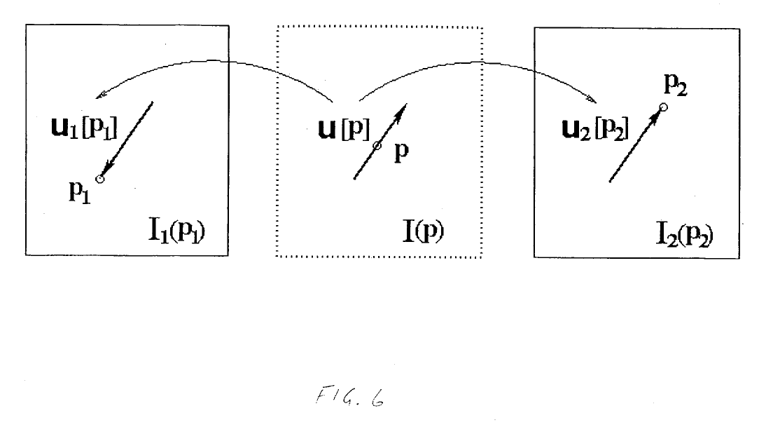

FIG. 5 illustrates the effect of a consistency constraint placed on the optical flow between two frames. According to the present invention, two-way consistency (from frame I₂ to frame I₁ and from frame I₁ to frame I₂) is enforced by computing a single flow field that satisfies the foregoing consistency constraint between image pair frames. To do so, the constant brightness constraint and the consistency constraint are merged to form a consistent brightness constraint:

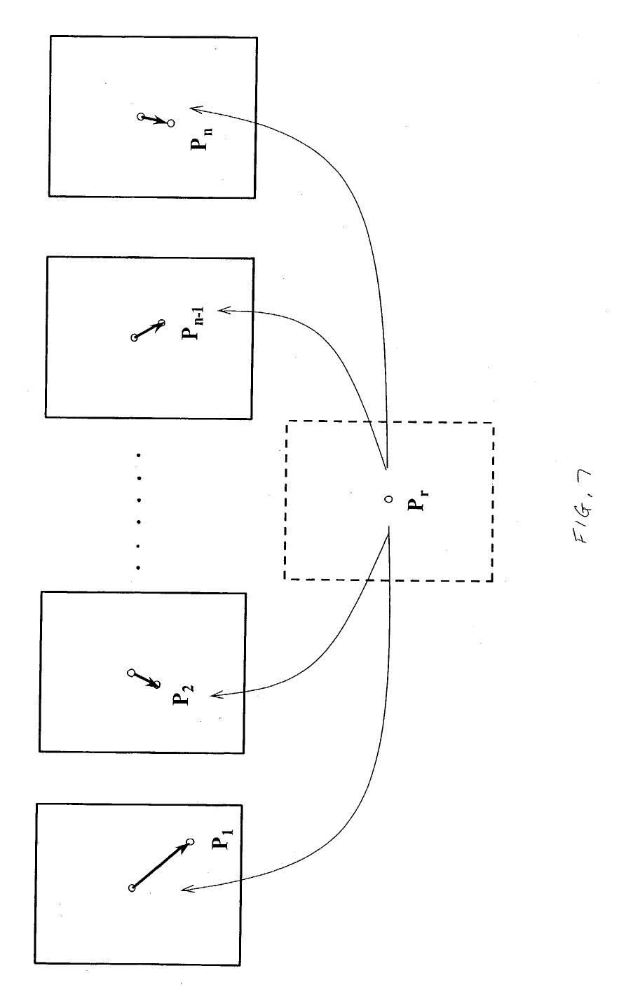

I(p)=I₁(p−αu[p])=I₂(p+(1−α)u[p]), (Equ. 5)

where I(p) is a reference frame between the two frames I₁(p₁) and I²(p₂), α is a control parameter that is in the range of [0,1]. The choice of the exact value for α depends on the statistics of the two frames. For example, if frame I₁ is noisier than frame I₂, then α should be chosen between 0 to 0.5. If frame I₂ is noisier than I₁, then α should be chosen between 0.5 to 1.0. Typically, when the statistics of the two frames are similar, then the value 0.5 should be chosen. To simplify the notations in the following presentation, we drop α and use its typical value 0.5 instead. Such simplification should not prevent the understanding that α can be and should be chosen appropriately depending on particular applications. More accurately, for this embodiment, the reference frame I(p) is a virtual (middle if α is 0.5) frame because the frame is typically not a real frame that is part of an image sequence (unless α is set to be 0 or 1). FIG. 6 illustrates the relationship of the reference frame with frames I₁ and I₂.

After a Taylor series expansion and the replacement of α with its typical value 0.5 the following differential form results:

$$\begin{matrix}{I}_{t} ( p ) {=}^{def} {I}_{1} ( p ) - {I}_{2} ( p ) \\ \approx \frac{1}{2} {( ∇ {I}_{1} ( p ) + ∇ {I}_{2} ( p ) )}^{T} u [ p ] .\end{matrix} \qquad ( Equ . 6 )$$

Note that all coordinates are in the virtual coordinate system p. An iterative version of the consistent brightness constraint can be readily derived. Advantages of computing consistent brightness and consistency constrained optical flows include that only one consistent optical flow needs to be estimated for an image pair, and that the estimated optical flow guarantees backward-forward consistency, and hence may be more accurate. Finally, if flow fields in the coordinate systems of frame I₁ and I₂ are required, they can be obtained by warping the flow field in the virtual frame coordinate, respectively.

Mathematically, one-sided optical flow methods generally tend to minimize the following one-directional least square error:

Errᵢ=(Iᵢ(pᵢ)−Iⱼ(pᵢ+uᵢ[pᵢ]))² (Equ. 7)

A better method is to minimize the total error:

Err=[Err₁+Err₂]. (Equ. 8)

However, a method of doing so that enforces consistency is to minimize the consistent least-square error:

Err_{cons}=[I₁(p−αu[p]−I₂(p+(1−α)u[p))]². (Equ. 9)

The foregoing has described computing consistent brightness optical flows from two image frames such that consistency is enforced. However, the principles of the present invention extend beyond two image frames to applications that benefit from determining optical flows from more than two image frames.

For example, the principles of the present invention are applicable to the computation of optical flows using three image frames. Three image frames, designated I₁, I₂, and I₃, can be used to determine two optical flow fields, designed as u₁ and u₃. Selecting I₂ as a reference frame, for example, two-frame methods generally compute the two optical flows u₁(p) and u₃(p) based on two independent constraints: I₁(p₁)=I(p) and I₃(p₃)=I(p). But, in doing so, consistency is not guaranteed because the two optical flows are computed independently.

According to the present invention, enforcing consistency between optical flows is enforced by adding the following constraint:

I₃(p)=I₁(p). (Equ. 10)

An iterative version based on that added constraint can be expressed in the common coordinate system p as:

$${{{I}_{t1}^{′} = {I}_{1}^{′} - I \approx \frac{1}{2} ( ∇ I + ∇ {I}_{1}^{′} ) )}^{T} δ {u}_{1} \\ {I}_{t3}^{′} = {I}_{3}^{′} - I \approx \frac{1}{2} ( ∇ I + ∇ {I}_{3}^{′} ) )}^{T} δ {u}_{3} \\ {I}_{t13}^{′} = {I}_{1}^{′} - {I}_{3}^{′} \approx \frac{1}{2} [ {( ∇ {I}_{1}^{′} )}^{T} δ {u}_{1} - {( ∇ {I}_{3}^{′} )}^{T} δ {u}_{3} ] \qquad ( Equ . 11 )$$

where I′ᵢ are the warped version of Iᵢ using motion from the previous iteration, and δu₁(p) and δu₃(p) are the incremental flows computed at each iteration.

If optical flow computations are restricted to one flow in a small window of an image, a Lucas-Kanade form of the previous equation at each iteration is:

$$⌊ \begin{matrix}2 \sum ( ∇ {I}_{1}^{′} ) {( ∇ {I}_{1}^{′} )}^{T} - \sum ( ∇ {I}_{1}^{′} ) {( ∇ {I}_{3}^{′} )}^{T} \\ - \sum ( ∇ {I}_{3}^{′} ) {( ∇ {I}_{1}^{′} )}^{T} 2 \sum ( ∇ {I}_{3}^{′} ) {( ∇ {I}_{3}^{′} )}^{T}\end{matrix} ⌋ \\ [ \begin{matrix}δ {u}_{1} \\ δ {u}_{3}\end{matrix} ] = [ \begin{matrix}{I}_{t1} ∇ {I}_{1}^{′} + {I}_{t13} ∇ {I}_{1}^{′} \\ {I}_{t3} ∇ {I}_{3}^{′} + {I}_{t31} ∇ {I}_{3}^{′}\end{matrix} ] \qquad ( Equ . 12 )$$

where Iₜ₃₁=−Iₜ₁₃.

In summary, the error to minimize in a three frame system is:

$$\begin{matrix}{Err}_{cons} = \sum [ {( {I}_{1} ( p - {u}_{1} [ p ] ) - I ( p ) )}^{2} + \\ {( {I}_{3} ( p - {u}_{3} [ p ] ) - I ( p ) )}^{2} + \\ {( {I}_{1} ( p - {u}_{1} [ p ] ) - {I}_{3} ( p - {u}_{3} [ p ] ) )}^{2} ] .\end{matrix} \qquad ( Equ . 13 )$$

In one embodiment, the present invention is extended to more than three frames. To illustrate, assume that there are n frames I₁, I₂, I₃, . . . Iₙ, and that computations are to compute all optical flows relative to a virtual coordinate (See FIG. 7). In one embodiment, the present invention can choose the coordinate of reference frame r as the virtual coordinate, for example. Under such choice, reference frame r's coordinates are the common coordinate system and that n−1 optical flow fields are to be computed. As shown in Equ. 13, when using three image frames the errors were minimized based on the sum of three errors for two optical flows. In general, these errors can be categorized as two types of errors: Err_{f2r}, which are errors between each frame and the reference frame (the diagonal components of the matrix to be shown), and Err_{f2f}, which are errors between a pair of frames other than the reference frame (the off-diagonal components of the matrix). For multiple optical flow field calculations the following error should be minimized:

$$\begin{matrix}{Err}_{cons} = \sum {Err}_{f2r} + {Err}_{f2f} \\ = {\sum }_{i \neq r} [ {( {I}_{i} ( p - {u}_{i} [ p ] ) - {I}_{r} ( p ) )}^{2} + \\ {\sum }_{i \neq j} {( {I}_{i} ( p - {u}_{i} [ p ] ) - {I}_{j} ( p - {u}_{j} [ p ] ) )}^{2} .\end{matrix} \qquad ( Equ . 14 )$$

After a first-order Taylor expansion, and by setting the Jacobin matrix to zero, the following linear system of equations at each iteration is:

$$[ \begin{matrix}( n - 1 ) \sum ( ∇ {I}_{1}^{′} ) {( ∇ {I}_{1}^{′} )}^{T} & - \sum ( ∇ {I}_{1}^{′} ) {( ∇ {I}_{2}^{′} )}^{T} & … & - \sum ( ∇ {I}_{1}^{′} ) {( ∇ {I}_{n}^{′} )}^{T} \\ … & … & … & … \\ - \sum ( ∇ {I}_{n}^{′} ) {( ∇ {I}_{1}^{′} )}^{T} & - \sum ( ∇ {I}_{1}^{′} ) {( ∇ {I}_{2}^{′} )}^{T} & … & ( n - 1 ) \sum ( ∇ {I}_{n}^{′} ) {( ∇ {I}_{n}^{′} )}^{T}\end{matrix} ] [ \begin{matrix}δ {u}_{1} \\ … \\ δ {u}_{n}\end{matrix} ] = [ \begin{matrix}\sum {I}_{t1j} ∇ {I}_{1}^{′} \\ … \\ \sum {I}_{tnj} {∇}_{n}^{′}\end{matrix} ] \qquad ( Equ . 15 )$$

where Iₜᵢⱼ=−Iₜⱼᵢ and Iₜⱼⱼ is actually Iₜⱼ. Notice that uᵣ is zero and is not included in the linear system.

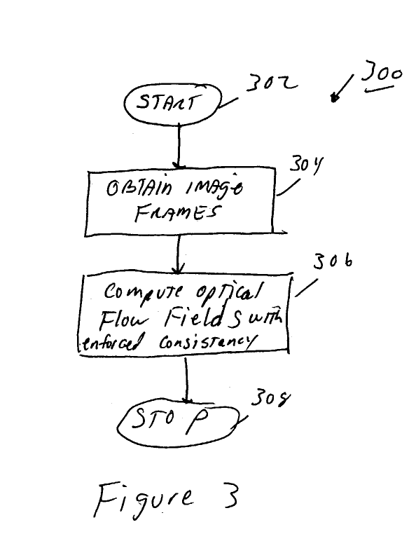

The general method of the present invention is illustrated in FIG. 3. As show, the method 300 starts at step 302 and proceeds to step 304 by obtaining image frames. Two, three or more image frames can be used. Then at step 306 one or more optical flow fields are computed in a manner that enforces consistency. Such computations are discussed above with referenced to a (virtual) reference frame. Then at step 308 the method stops.

The multiple-frame based error minimized above does not take into consideration consistency between each pair of frames. That is difficult for pairs of frames other than the reference frame since to enforce pair-wise consistency, a virtual coordinate system for each pair of frames would be required.

However, it is possible to first compute consistent pair-wise flows u_{j,i+1}, and then cascade the consistent flows to obtain the initial flow estimates uⱼ from frame j to the reference frame. Finally, the initial flow estimates can be bundled according to Equ. 15.

Experimental results using synthetic data having synthetic motion has shown that sub-pixel motion can be determined using the foregoing methods. To demonstrate the improvement of optical flow computations, the foregoing optical flow methods have been applied to a super-resolution method using semi-synthetic data where flow is unknown. The present invention is also applicable to flow-based super-resolution optical flow processes. For example, video sequences captured with digital video camcorders.

It should be noted that when the present invention computes consistent flow field between two frames I₁ and I₂, a reference frame I(p) between these two frames is produced. An image process that generates such in-between frame is commonly referred to as image morphing or tweening. Hence, the present method provides an alternative to morphing or tweening in addition to flow estimation.

Although various embodiments which incorporate the teachings of the present invention have been shown and described in detail herein, those skilled in the art can readily devise many other varied embodiments that still incorporate these teachings.

What is claimed is:

1. A method for computing optical flow comprising the steps of:
a) obtaining a first image frame and a second image frame; and
b) computing an optical flow field using said first and second image frames, wherein said computed optical flow field is derived by enforcing an optical flow consistency constraint between said first and second image frames.

2. The method of claim 1, wherein said computing step b) computes said optical flow field relative to a virtual reference frame.

3. The method of claim 1, wherein said computed optical flow field is based on brightness constancy.

4. The method of claim 1, wherein the computed optical flow field is determined according to a consistency constraint:
p₂=p₁+u₁[p₁] u₂[p₂]=−u₁[p₁]
where p₁ are coordinates in said first image frame, where p₂ are coordinates in said second image frame, where u₁[p₁] is a first flow field, and where field where u₂[p₂] is a second flow field.

5. The method of claim 1, wherein said optical flow consistency constraint is provided by:
I(p)=I₁(p−αu[p])=I₂(p+(1−α)u[p]),
where α is a control parameter, where I(p) is a reference frame, where I₁(p) is said first reference frame, where I₂(p) is said second reference frame, and where u[p] is said optical flow field.

6. The method of claim 5, wherein said optical flow consistency constraint is expressed in differential form:
$$\begin{matrix}{I}_{t} ( p ) {=}^{def} {I}_{1} ( p ) - {I}_{2} ( p ) \\ \approx \frac{1}{2} {( ∇ {I}_{1} ( p ) + ∇ {I}_{2} ( p ) )}^{T} u [ p ] .\end{matrix}$$
where said α is set to be 0.5.

7. The method of claim 5, wherein said control parameter a is set in a range of [0,1].

8. The method of claim 1, wherein the computed optical flow is determined to minimize the error: Err_{cons}=[I₁(p−αu[p]−I₂(p+(1−α)u[p))]²,
where α is a control parameter, where I₁(p) is said first reference frame, where I₂(p) is said second reference frame, and where u[p] is said optical flow field.

9. The method of claim 1, further comprising the step of:
c) obtaining flow fields in coordinates of said first image frame or said second image frame by warping said optical flow.

10. The method of claim 1, where said optical flow field is used to detect salient motion.

11. The method of claim 1, where said optical flow field is used to generate a reconstruction-based super-resolution image.

12. The method of claim 2, wherein said virtual reference frame is used in a tweening method.

13. A method of computing optical flow comprising the steps of:
a) obtaining a first image frame, a second image frame and a third frame; and
b) computing a plurality of optical flow fields using said first, second and third image frames, wherein said computed optical flow fields are derived by enforcing an optical flow consistency constraint between said first, second and third image frames.

14. The method of claim 13, wherein said computing step b) computes said optical flow fields relative to said second frame, wherein said computed optical flow fields are such that an optical flow field computed from said first image frame to said second image frame is consistent with an optical flow field computed from said third image frame to said second image frame.

15. The method of claim 13, wherein the computed optical flow field is based on brightness constancy.

16. The method of claim 13, wherein said optical flow consistency constraint is provided by:
$${{{I}_{t1}^{′} = {I}_{1}^{′} - I \approx \frac{1}{2} ( ∇ I + ∇ {I}_{1}^{′} ) )}^{T} δ {u}_{1} \\ {I}_{t3}^{′} = {I}_{3}^{′} - I \approx \frac{1}{2} ( ∇ I + ∇ {I}_{3}^{′} ) )}^{T} δ {u}_{3}$$
$${I}_{t13}^{′} = {I}_{1}^{′} - {I}_{3}^{′} \approx \frac{1}{2} [ {( ∇ {I}_{1}^{′} )}^{T} δ {u}_{1} - {( ∇ {I}_{3}^{′} )}^{T} δ {u}_{3} ]$$
where δu₁ is an incremental optical flow field computed from said first image frame,
where δu₃ is an incremental optical flow field computed from said third image frame,
and where I is a reference frame, and I′ᵢ are warped version of Iᵢ.

17. The method of claim 16, wherein said optical flow consistency constraint is expressed in a linear system of equations:
$$⌊ \begin{matrix}2 \sum ( ∇ {I}_{1}^{′} ) {( ∇ {I}_{1}^{′} )}^{T} - \sum ( ∇ {I}_{1}^{′} ) {( ∇ {I}_{3}^{′} )}^{T} \\ - \sum ( ∇ {I}_{3}^{′} ) {( ∇ {I}_{1}^{′} )}^{T} 2 \sum ( ∇ {I}_{3}^{′} ) {( ∇ {I}_{3}^{′} )}^{T}\end{matrix} ⌋ [ \begin{matrix}δ {u}_{1} \\ δ {u}_{3}\end{matrix} ] = [ \begin{matrix}{I}_{t1} ∇ {I}_{1}^{′} + {I}_{t13} ∇ {I}_{1}^{′} \\ {I}_{t3} ∇ {I}_{3}^{′} + {I}_{t31} ∇ {I}_{3}^{′}\end{matrix} ]$$
where Iₜ₃₁=−Iₜ₁₃.

18. The method of claim 13, wherein the computed optical flow fields are computed so as to minimize an error between said first frame and said second frame and to minimize an error between said first frame and said third frame.

19. The method of claim 18, wherein said errors are provided as:
$$\begin{matrix}{Err}_{cons} = \sum [ {( {I}_{1} ( p - {u}_{1} [ p ] ) - I ( p ) )}^{2} + \\ {( {I}_{3} ( p - {u}_{3} [ p ] ) - I ( p ) )}^{2} + \\ {( {I}_{1} ( p - {u}_{1} [ p ] ) - {I}_{3} ( p - {u}_{3} [ p ] ) )}^{2} ]\end{matrix}$$
where I is said second image frame that is serving as a reference frame, where I₁ is said first image frame, where I₃ is said third image frame, where u₁[p] is an optical flow field computed from said first image frame, and where u₃[p] is an optical flow field computed from said third image frame.

20. The method of claim 13, where said optical flow fields are used to detect salient motion.

21. The method of claim 13, where said optical flow fields are used to generate a reconstruction-based super-resolution image.

22. A method for computing optical flow comprising the steps of:
a) obtaining N number of image frames; and
b) computing N−1 optical flow fields using said N number of image frames, wherein said computed optical flow fields are derived by enforcing an optical flow consistency constraint between one of said N frames and a reference image frame r.

23. The method of claim 22, wherein said computed optical flow fields are computed so as to minimize errors between one of said N frames and the reference frame r and errors between two of said N frames other than the reference frame r.

24. The method of claim 23, wherein said computed optical flow fields are computed so as to minimize the following:
$$\begin{matrix}{Err}_{cons} = \sum {Err}_{f 2 r} + {Err}_{f 2 f} \\ = {\sum }_{i \neq r} [ {( {I}_{i} ( p - {u}_{i} [ p ] ) - {I}_{r} ( p ) )}^{2} + \\ {\sum }_{i \neq j} {( {I}_{i} ( p - {u}_{i} [ p ] ) - {I}_{j} ( p - {u}_{i} [ p ] ) )}^{2} .\end{matrix}$$
wherein Err_{f2r} are said errors between one of said N frames and the reference frame r; wherein Err_{f2f} are said errors between two of said N frames other than the reference frame r, where Iᵢ is one of said N image frames, where Iⱼ is one of said N image frames and where Iᵣ is said reference image frame.

25. The method of claim 22, wherein the computed optical flow fields are based on brightness constancy.

26. The method of claim 24, wherein the computed optical flow fields are based the following linear system of equations:
$$[ \begin{matrix}( n - 1 ) \sum ( ∇ {I}_{1}^{′} ) {( ∇ {I}_{1}^{′} )}^{T} & - \sum ( ∇ {I}_{1}^{′} ) {( ∇ {I}_{2}^{′} )}^{T} … & - \sum ( ∇ {I}_{1}^{′} ) {( ∇ {I}_{n}^{′} )}^{T} \\ ⋯ & ⋯ ⋯ & ⋯ \\ - \sum ( ∇ {I}_{n}^{′} ) {( ∇ {I}_{1}^{′} )}^{T} & - \sum ( ∇ {I}_{1}^{′} ) {( ∇ {I}_{2}^{′} )}^{T} … & ( n - 1 ) \sum ( ∇ {I}_{n}^{′} ) {( ∇ {I}_{n}^{′} )}^{T}\end{matrix} ] [ \begin{matrix}δ {u}_{1} \\ ⋯ \\ δ {u}_{n}\end{matrix} ] = [ \begin{matrix}\sum {I}_{t1j} ∇ {I}_{1}^{′} \\ ⋯ \\ \sum {I}_{tnj} {∇}_{n}^{′}\end{matrix} ] .$$

27. An apparatus for computing optical flow comprising:
means for obtaining a first image frame and a second image frame; and
means for computing an optical flow field using said first and second image frames, wherein said computed optical flow field is derived by enforcing an optical flow consistency constraint between said first and second image frames.

28. An apparatus for computing optical flow comprising:
means for obtaining a first image frame, a second image frame and a third frame; and
means for computing a plurality of optical flow fields using said first, second and third image frames, wherein said computed optical flow fields are derived by enforcing an optical flow consistency constraint between said first, second and third image frames.
